(19) United States
(12) Patent Application Publication
(10) Pub. No.: US 2019/0319221 A1
(43) Pub. Date: Oct. 17, 2019

(54) METHOD OF MANUFACTURING DISPLAY APPARATUS, DISPLAY APPARATUS, AND ELECTRONIC APPARATUS

(71) Applicant: Sony Semiconductor Solutions Corporation, Kanagawa (JP)

(72) Inventor: Tomokazu Ohchi, Kanagawa (JP)

(21) Appl. No.: 16/469,822

(22) PCT Filed: Oct. 26, 2017
(86) PCT No.: PCT/JP2017/038696

§ 371 Date: Jun. 14, 2019

(30) Foreign Application Priority Data
Dec. 21, 2016 (JP) 2016-247457

(51) Int. Cl. H01L 51/56; H01L 51/00; H01L 23/00; H01L 51/52

(52) U.S. Cl. CPC H01L 51/56; H01L 2224/03614; H01L 24/89; H01L 51/5215; H01L 24/08; H01L 24/03; H01L 24/05; H01L 2251/301; H01L 2251/308; H01L 2224/80203; H01L 2224/08225; H01L 2224/08501; H01L 2224/0381; H01L 2224/05569; H01L 2224/0579; H01L 2224/05124; H01L 2224/05147; H01L 51/0023

(57) ABSTRACT

A method of manufacturing a display apparatus in which corrosion of an electrode due to a battery reaction does not occur, and corresponding apparatuses with excellent display characteristics are disclosed. In one example, the method includes forming a first electrode having a first conductive material and connected thereto a second electrode having a second conductive material respectively inside and outside a display area. First opening portions are formed on an interlayer insulation film that covers the electrodes such that a part of the first electrode is exposed. Second opening portions similarly leave a part of the second electrode exposed. An anisotropic conductive layer is formed on the exposed second electrode, and then the first opening portions, the second opening portions, and the interlayer insulation film are exposed to a liquid containing an electrolyte.

### TECHNICAL FIELD

The present technology relates to a method of manufacturing a display apparatus, a display apparatus, and an electronic apparatus.

### BACKGROUND ART

An organic EL (Electro Luminescence) display apparatus includes an organic EL element provided for each display pixel and a TFT (Thin Film Transistor) circuit that controls light emission of the organic EL element, and performs image displaying by supplying a current to the organic EL element. The organic EL element has a structure in which an anode electrode and a cathode electrode sandwich an organic EL layer. The organic EL layer has a structure in which a hole transport layer, a light emission layer, and an electron transport layer are sequentially laminated. When a voltage is applied to the anode electrode and the cathode electrode, electrons and holes are flown into the organic EL layer from the cathode electrode and the anode electrode, respectively, and the electrons and the holes are recoupled by light emission molecules in the light emission layer, thereby emitting light. In related art, for the anode electrode, an AlCu alloy is used. As a hole injection electrode, using an ITO (Indium Tin Oxide) having a high work function has been proposed.

In a manufacturing process of the organic EL display apparatus, an anode electrode made of an ITO is formed in a display area. After that, an interlayer insulation film is formed so as to cover the anode electrode. At this time, a pad electrode made of an AlCu alloy or the like for connection with an external wiring disposed outside of the display area is also covered with the interlayer insulation film. The pad electrode and the anode electrode are electrically connected by a wiring or the like disposed in the interlayer insulation film. Subsequently, the interlayer insulation film corresponding to the pad electrode is removed, and the pad electrode is exposed. After that, a part of the interlayer insulation film is removed by dry etching to define an opening portion of a pixel, and the anode electrode is exposed. After the interlayer insulation film is removed by dry etching, in order to remove residue which is caused by the etching and remains in the vicinity of the anode electrode, substrate cleaning is performed with an organic cleaning solution as a cleaning solution containing an electrolyte.

At a time of cleaning with the organic cleaning solution after the dry etching, the anode electrode and the pad electrode are exposed to the cleaning solution at the same time, which causes a battery reaction and raises a problem in that the anode electrode is corroded. A pixel in which the corrosion is caused becomes a dark spot when used as a display apparatus, which results in deterioration of display characteristics.

In order to prevent the corrosion of the anode electrode caused by the battery reaction as described above, for example, there has been proposed a structure in which the pad electrode is covered with a light-shielding cover portion made of the same material as the anode electrode, thereby preventing an occurrence of a battery effect (see Patent Literature 1).

### CITATION LIST

### Patent Literature

Patent Literature 1: Japanese Patent Application Laid-open No. 2010-185903

### DISCLOSURE OF INVENTION

### Technical Problem

In view of the circumstances as described above, an object of the present technology is to provide a method of manufacturing a display apparatus, a display apparatus, and an electronic apparatus, in which corrosion of the electrode due to the battery reaction is not caused, and which is excellent in display characteristics.

### Solution to Problem

To achieve the above object, a method of manufacturing a display apparatus according to an embodiment of the present technology includes:

forming a first electrode having a first conductive material on a substrate;

forming, on the substrate, a second electrode having a second conductive material different from the first conductive material, the second electrode being electrically connected to the first electrode;

forming an interlayer insulation film to cover the first electrode and the second electrode;

forming a first opening portion on the interlayer insulation film and causing at least a part of the first electrode to be exposed;

forming a second opening portion on the interlayer insulation film and causing at least a part of the second electrode to be exposed;

forming an anisotropic conductive layer on the exposed second electrode; and

exposing, after the anisotropic conductive layer is formed, the first opening portion, the second opening portion, and the interlayer insulation film to a liquid containing an electrolyte.

By the manufacturing method, at the time when the first opening portion, the second opening portion, and the interlayer insulation film are exposed to the liquid containing the electrolyte, on the second electrode, the anisotropic conductive layer is formed, so a battery effect due to the liquid containing the electrolyte is not generated, and electrical corrosion of the first electrode is prevented. Therefore, in the case where the first electrode forms pixels in the display area, it is possible to prevent an occurrence of a dark spot due to electrical corrosion of the first electrode, and it is possible to obtain a display apparatus excellent in display characteristics.

Here, in the case where the anisotropic conductive layer is not formed, the first electrode and the second electrode which are electrically connected and are different kinds of metals are exposed to the liquid containing the electrolyte with the electrodes exposed to outside, so a battery effect is generated between the first electrode and the second electrode is generated. As a result, corrosion of the first electrode occurs. In this way, when corrosion of the first electrode occurs, for example, in the case where the first electrode forms a pixel, the pixel becomes a dark spot when a display apparatus is formed, resulting in deterioration of a display characteristic. In contrast, in the present technology, because the anisotropic conductive layer is formed on second electrode, the anisotropic conductive layer prevents the second electrode from being in contact with the liquid containing the electrolyte. Further, because the anisotropic conductive layer has an insulation property until thermal compression bonding is performed, a battery effect is not generated, so the electrode is not subjected to corrosion. Therefore, in the case where the first electrode forms the pixel of the display apparatus, an occurrence of a dark spot due to corrosion of the electrode is prevented, and it is possible to obtain a display apparatus excellent in display characteristics.

The first electrode may be formed in a display area of the substrate, and the second electrode may be formed in a first area outside of the display area of the substrate.

As a result, an occurrence of a dark spot due to corrosion of the electrode is prevented, and it is possible to obtain a display apparatus excellent in display characteristics.

The interlayer insulation film may include a first interlayer insulation film, a second interlayer insulation film, and a third interlayer insulation film. The second electrode may be formed on the first interlayer insulation film. After the second electrode is formed, on the second electrode and the first interlayer insulation film, the second interlayer insulation film may be formed. After the second interlayer insulation film is formed, on the second interlayer insulation film, the first electrode may be formed. After the first electrode is formed, on the first electrode and the second interlayer insulation film, the third interlayer insulation film may be formed.

As a result, the first electrode is positioned higher than the second electrode in a thickness direction of the interlayer insulation film by a thickness of the second interlayer insulation film. As a result, an opening depth of the second opening portion formed so as to correspond to the second electrode is deeper than an opening depth of a first opening portion formed so as to correspond to the first electrode.

The anisotropic conductive layer may be formed by forming an anisotropic conductive film on an exposed portion of the first electrode, an exposed portion of the second electrode, and the interlayer insulation film, and performing ashing for the anisotropic conductive film by using EPD control in such a manner that the anisotropic conductive film remains only on the exposed second electrode.

By performing ashing by using the EPD control as described above, it is possible to perform control so as to selectively form the anisotropic conductive layer on the second electrode.

That is, on the first interlayer insulation film, the second electrode is formed. After the second electrode is formed, on the second electrode and the first interlayer insulation film, the second interlayer insulation film is formed. After the second interlayer insulation film is formed, on the second interlayer insulation film, the first electrode is formed. After the first electrode is formed, on the first electrode and the second interlayer insulation film, the third interlayer insulation film is formed. As a result, the first electrode is positioned higher than the second electrode in a thickness direction of the interlayer insulation film by a thickness of the second interlayer insulation film. As a result, in the state in which the and second opening portions are formed on the interlayer insulation film, and the first electrode and the second electrode are exposed to outside, the second opening portion has an opening depth deeper than the first opening portion.

In the state in which the first and second opening portions respectively corresponding to the first electrode and second electrode are formed, in the case where the anisotropic conductive film are formed on an entire substrate, and etching is performed therefor to form the anisotropic conductive layer, a film thickness of the anisotropic conductive film formed on the second electrode is thicker than a film thickness of the anisotropic conductive film formed in an area outside thereof in the state in which the anisotropic conductive film is formed on the entire substrate. Thus, when the anisotropic conductive film is removed by ashing uniformly on a plane of the substrate, at a time when the anisotropic conductive film formed in the area outside of the second electrode is removed, only on the second electrode, the anisotropic conductive film remains. As described above, by using a difference of the opening depths of the first opening portion and the second opening portion, on the second electrode, the anisotropic conductive layer can be selectively formed.

The anisotropic conductive layer may be formed by forming an anisotropic conductive film including a light curing resin on an exposed portion of the first electrode, an exposed portion of the second electrode, and the interlayer insulation film, and causing the anisotropic conductive film to be exposed to light and performing development in such a manner that the anisotropic conductive film remains only on the exposed second electrode.

As described above, a material for which photoetching can be performed may be used to form the anisotropic conductive layer by photolithography. In the development process by photolithography, because the anisotropic conductive layer is formed on the second electrode, it is possible to prevent an occurrence of a battery reaction due to immersion in a developer, and prevent an occurrence of electrical corrosion of the electrode.

The second electrode and a wiring substrate may be disposed to face each other through the anisotropic conductive layer, and the second electrode and the wiring substrate may be electrically connected by thermal compression bonding.

As described above, the second electrode can be used as an external connection terminal, and the anisotropic conductive layer can also be used to connect with the wiring substrate. As described above, the anisotropic conductive layer can be used to prevent an occurrence of the battery effect and to perform connection to outside.

The first conductive material and the second conductive material may have different oxidation-reduction potentials.

The first conductive material may be a transparent conductive material, and the second conductive material may be a material containing aluminum.

The first conductive material may be an indium tin oxide, and the second conductive material may be an aluminum copper alloy.

The first electrode may have a laminated structure of a first conductive layer made of the second conductive material and a second conductive layer that is provided on the first conductive layer and made of the first conductive material.

The first electrode may be formed in a second area outside of a display area of the substrate, and the second electrode may be formed in a first area outside of the display area of the substrate.

To achieve the above object, a display apparatus according to an embodiment of the present technology includes a substrate, an organic electroluminescence element, a second electrode, and an anisotropic conductive layer.

The substrate includes a display area.

The organic electroluminescence element includes a first electrode that is provided in the display area and has a first conductive material, an organic electroluminescence layer provided on the first electrode, and a third electrode provided on the organic electroluminescence layer.

The second electrode that is provided outside of the display area of the substrate, is electrically connected to the first electrode, and has a second conductive material having the first conductive material.

The anisotropic conductive layer is provided on the second electrode.

With this configuration, it is possible to obtain a display apparatus excellent in display characteristics. That is, in a manufacturing process of the display apparatus, at a time when the substrate is exposed to the liquid containing an electrolyte, the first electrode is exposed to outside, and the substrate can be exposed to the liquid containing the electrolyte with the anisotropic conductive layer formed on the second electrode. Thus, a battery effect due to the liquid containing the electrolyte is not generated, and electrical corrosion of the first electrode is prevented. Therefore, it is possible to prevent an occurrence of a dark spot due to electrical corrosion of the first electrode that forms a pixel of the display area. It is possible to obtain a display apparatus excellent in display characteristics.

The first conductive material and the second conductive material may have different oxidation-reduction potentials.

The display apparatus may further include a wiring substrate electrically connected to the second electrode through the anisotropic conductive layer.

As described above, the second electrode may be used as an external connection terminal, and may also be used to perform connection to the anisotropic conductive layer.

To achieve the object, an electronic apparatus according to the present technology includes a display apparatus.

The display apparatus includes a substrate including a display area, an organic electroluminescence element including a first electrode that is provided in the display area and has a first conductive material, an organic electroluminescence layer provided on the first electrode, and a third electrode provided on the organic electroluminescence layer, a second electrode that is provided outside of the display area of the substrate, is electrically connected to the first electrode, and has a second conductive material having the first conductive material, and an anisotropic conductive layer provided on the second electrode.

### Advantageous Effects of Invention

As described above, according to the present technology, it is possible to obtain a method of manufacturing a display apparatus in which corrosion of an electrode by a battery reaction is not caused, a display apparatus, and an electronic apparatus.

It should be noted that the effects described herein are not necessarily limited, any effect described in this disclosure may be obtained.

### BRIEF DESCRIPTION OF DRAWINGS

FIG. 1 A schematic plan view showing an organic EL display apparatus according to an embodiment of the present technology.

FIG. 2 A partial schematic cross-sectional view of the organic EL display apparatus shown in FIG. 1, and a schematic view for explaining a connection state between a pad electrode in a pad area and an anode electrode in a display area.

FIG. 3 A process diagram (Part 1) showing a method of manufacturing an organic EL display apparatus according to a first embodiment.

FIG. 4 A process diagram (Part 2) showing a method of manufacturing an organic EL display apparatus according to the first embodiment.

FIG. 5 A process diagram showing a method of manufacturing an organic EL display apparatus according to a second embodiment.

FIG. 6 A process diagram showing a method of manufacturing an organic EL display apparatus according to a third embodiment.

FIG. 7 A partial schematic view showing an organic EL display apparatus according to another embodiment.

FIG. 8 A schematic partial cross-sectional view of a vicinity of an anode electrode showing a state in which the anode electrode is corroded.

FIG. 9 An external view of a digital camera to which the organic EL display apparatus according to an embodiment of the present technology is applied.

FIG. 10 An external view of a one-eye display module of an eyewear type, to which the organic EL display apparatus according to an embodiment of the present technology is applied.

### MODE(S) FOR CARRYING OUT THE INVENTION

Hereinafter, embodiments of the present technology will be described with reference to the drawings. The present technology can be applied to an object manufactured through a process of being subjected to a cleaning solution in a state in which a plurality of different kinds of metals to be electrically connected are exposed. In this embodiment, a description will be given by using an example of, as a display apparatus, an organic electroluminescence display apparatus (hereinafter, referred to as organic EL display apparatus) provided with an organic electroluminescence element (hereinafter, referred to as organic EL element) as a light emission element.

### Outline of Display Apparatus

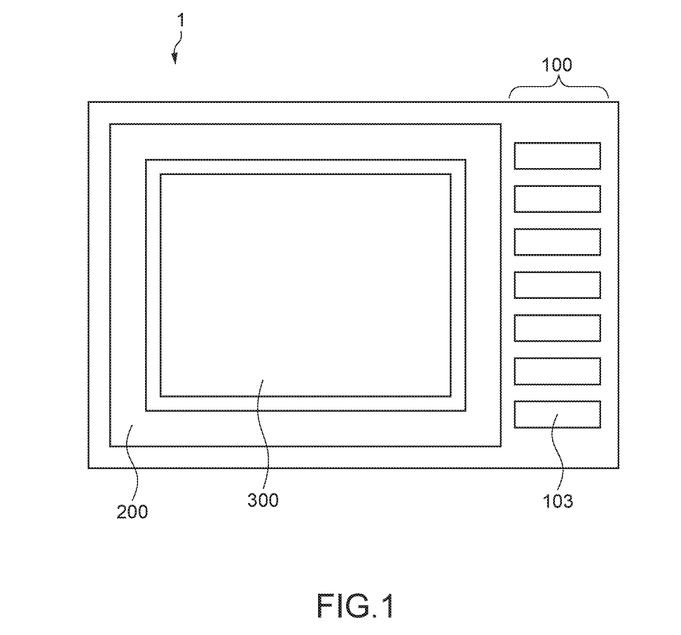

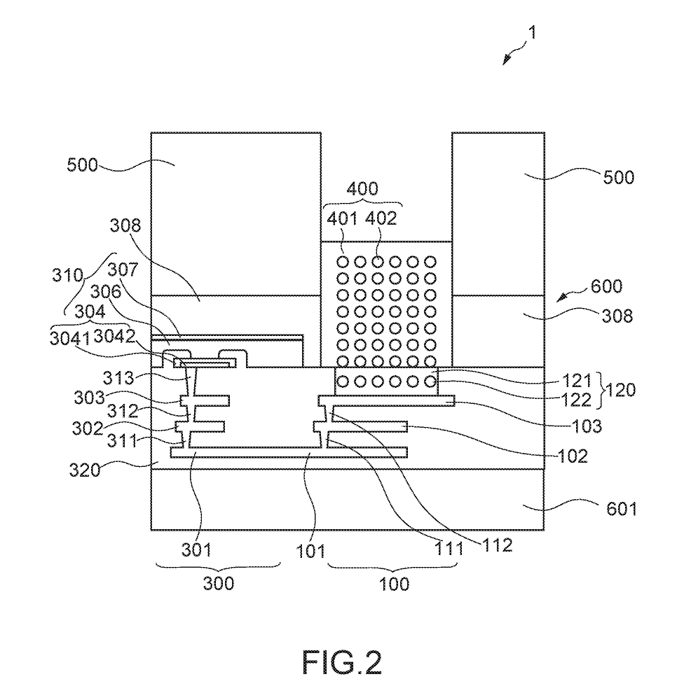

FIG. 1 is a schematic plan view of an organic EL display apparatus according to an embodiment of the present technology. FIG. 2 is a schematic partial cross-sectional view showing the organic EL display apparatus. FIG. 2 shows the schematic cross-sectional view of a pad area and a display area of the organic EL display apparatus shown in FIG. 1, and the schematic view for explaining a connection state between the pad electrode and the anode electrode in the display area.

An organic EL display apparatus 1 includes a display area 300 provided substantially in a center potion, a cathode contact area 200 as a second area, which is provided so as to surround the display area 300, and a pad area 100 as a first area, which is provided on an end portion of a semiconductor substrate 600. The cathode contact area 200 and the pad area 100 are disposed outside of the display area 300.

The organic EL display apparatus 1 includes an organic EL display panel, a flexible wiring substrate (not shown) electrically connected to the organic EL display panel through an ACF (Anisotropic Conductive Film) 400, and a circuit substrate (not shown) electrically connected to the flexible wiring substrate. The organic EL display panel is constituted of the semiconductor substrate 600 and a sealing substrate 500.

The semiconductor substrate 600 is a substrate which has a rectangular shape in a plan view and includes a substrate 601, a switching element provided on the substrate 601, various wirings, and an organic EL element. The sealing substrate 500 is a substrate which has a rectangular shape in a plan view and which includes a color filter. The sealing substrate 500 is disposed so as to face the semiconductor substrate 600. The semiconductor substrate 600 and the sealing substrate 500 are adhered by a resin adhesive and constitute the organic EL display panel. The circuit substrate is a substrate on which a power supply for driving a switching element in the display area to be described later and a drive circuit such as a signal output circuit for inputting various signals are mounted. The flexible wiring substrate is a substrate for electrically connecting the circuit substrate and the organic EL display panel.

It should be noted that in this embodiment, the drive circuit is provided on a drive circuit substrate, but the drive circuit may be provided on the semiconductor substrate 600.

In the pad area 100, a plurality of pad electrodes 103 are provided. The pad electrodes 103 and the flexible wiring substrate are electrically connected through an anisotropy conductive layer 120 and the ACF (Anisotropic Conductive Film) 400. The ACF 400 is a conductive film obtained by forming, into a film shape, a mixture of fine metal particles 402 into a thermosetting resin 401.

In the display area 300, a plurality of pixels are disposed in a vertical and horizontal matrix pattern. The pixels each include an organic EL element 310 and a TFT (Thin Film Transistor, hereinafter, referred to as transistor) as a switching element for controlling light emission of the organic EL element 310. The transistor includes a gate, a source, and a drain.

As the transistor, a drive transistor and a sampling transistor are provided. The drive transistor drives the organic EL element 310. The sampling transistor supplies a signal potential supplied from a signal output circuit to a gate of the drive transistor.

The organic EL element 310 is obtained by laminating an anode electrode 304 as a first electrode, which is a lower electrode, an organic EL (electroluminescence) layer 306, and a cathode electrode 307 as a third electrode, which is an upper electrode.

The anode electrode 304 as the first electrode has a laminated structure of a first conductive layer 3041 and a second conductive layer 3042 formed on the first conductive layer 3041. The first conductive layer 3041 is an AlCu layer 3041 made of AlCu (aluminum copper alloy) as a material containing Al as a second conductive material different from a first conductive material. The second conductive layer 3042 is an ITO layer 3042 made of ITO (Indium Tin Oxide) as a transparent conductive material as the first conductive material. The ITO layer 3042 is disposed so as to be adjacent to the organic EL layer 306. The organic EL layer 306 has a configuration in which the hole transport layer, the light emission layer, and the electron transport layer are sequentially laminated. The hole transport layer is disposed on the anode electrode 304 side, and the electron transport layer is disposed on the cathode electrode 307 side.

In the display area 300, on the substrate 601, a signal line is disposed along a column direction of the pixels, and along a row direction of the pixel, a scanning line and a power supply line. A wiring 101 including the signal line, the scanning line, and the power supply line are led to the pad electrodes 103 as a second electrode as the pad area 100 outside of the display area 300, respectively.

In the cathode contact area 200, a cathode common wiring that is electrically connected with the cathode electrode 307 is disposed. The cathode electrode 307 for each pixel is connected to the cathode common wiring that is common to all pixels. To the cathode common wiring, a cathode potential is supplied from a cathode power supply. The cathode electrode 307 and the cathode common wiring are respectively connected through the wiring, and a leading wiring electrically connected with the cathode common wiring is led to the pad electrodes 103 of the pad area 100.

The pad electrodes 103 are respectively electrically connected to the signal line, the scanning line, the power supply line, and the leading wiring connected to the cathode common wiring. Signals supplied to the pad electrodes 103 differ depending on a kind of the wiring connected to the pad electrode 103. In this embodiment, irrespective of the kinds of the wirings, external terminals to which signals or the like are supplied from outside are collectively referred to as the pad electrodes 103. The scanning line, the signal line, the power supply line, the leading wiring connected to the cathode common wiring which are electrically connected to the pad electrodes 103 are collectively referred to as the wiring 101.

A source of the drive transistor is electrically connected to the anode electrode 304, and a drain thereof is electrically connected to the power supply line. A gate of the sampling transistor is electrically connected to the scanning line, a drain thereof is electrically connected to the signal line, and a source thereof is electrically connected to a gate of the drive transistor.

As shown in FIG. 2, in the display area 300, on the substrate 601, a plurality of metal layers 301, 302, and 303, an interlayer insulation film 320, the organic EL element 310, connection holes 311, 312, and 313, and a protection film 308 are disposed. The interlayer insulation film 320 is intervened between the metal layers 301 to 303 and the organic EL element 310. The connection holes 311 to 313 are formed on the interlayer insulation film 320, and electrically connect the plurality of metal layers 301 to 303 with the anode electrode 304 of the organic EL element 310. The metal layers 301 to 303 or a metal layer formed of the same layer as the metal layers 301 to 303 and the interlayer insulation film 320 constitute the transistor and the like, the wiring 101 is configured by the same layer as the metal layer 301.

In the pad area 100, on the substrate 601, disposed are the wiring 101 that is formed of the same layer as the metal layer 301 in the display area 300 and is connected to the metal layer 301, a metal layer 102, a metal layer 103 (hereinafter, referred to as pad electrodes 103) as a pad electrode, which is an external connection terminal unit, the wiring 101, the interlayer insulation film 320 intervened between the metal layers 102 and 103, and the anisotropy conductive layer 120 provided on the pad electrodes 103. The pad electrodes 103 is made of the first conductive material that is the same as the AlCu layer 3042 as a first conductive layer disposed below the anode electrode 304 having a two-layer laminated structure.

The anisotropy conductive layer 120 is a layer obtained by mixing a fine metal particle 122 in a thermosetting resin 121. The anisotropy conductive layer 120 is pressed with the ACF 400 and electrically connects the flexible wiring substrate and the pad electrodes 103 in a form of the organic EL display apparatus 1.

In the cathode contact area 200, on the substrate 601, as in the display area 300, disposed are the wiring 101 electrically connected to the pad electrodes 103 provided in the pad area 100, a plurality of metal layers, a metal layer formed by laminating an AlCu layer and an ITO layer (first electrode), and the interlayer insulation film 320 intervened between those wirings and the metal layers. On the metal layer formed by laminating the AlCu layer and the ITO layer, a cathode contact layer provided with the same layer as the cathode electrode is formed. Further, on an entire surface of the substrate including the cathode contact layer, the protection film 308 is provided.

In this way, the anode electrode 304 of the organic EL element 310 provided in the display area 300 and the pad electrodes 103 provided in the pad area 100 are electrically connected through the wiring 101 and the like. The anode electrode 304 is formed by laminating the AlCu layer 3041 and the ITO layer 3042, and the pad electrode 103 is configured by the AlCu layer.

Further, the same holds true for the cathode contact area 200. The ITO layer provided in the cathode contact area 200 and the pad electrodes 103 are electrically connected through the wiring 101 or the like.

The pad electrodes 103 made of AlCu, the ITO layer 3042 of the anode electrode 304 formed in the display area 300, and the ITO layer formed in the cathode contact area 200 are metals, the kind of which are different from one another, and have oxidation-reduction potentials different from one another.

### Method of Manufacturing Display Apparatus

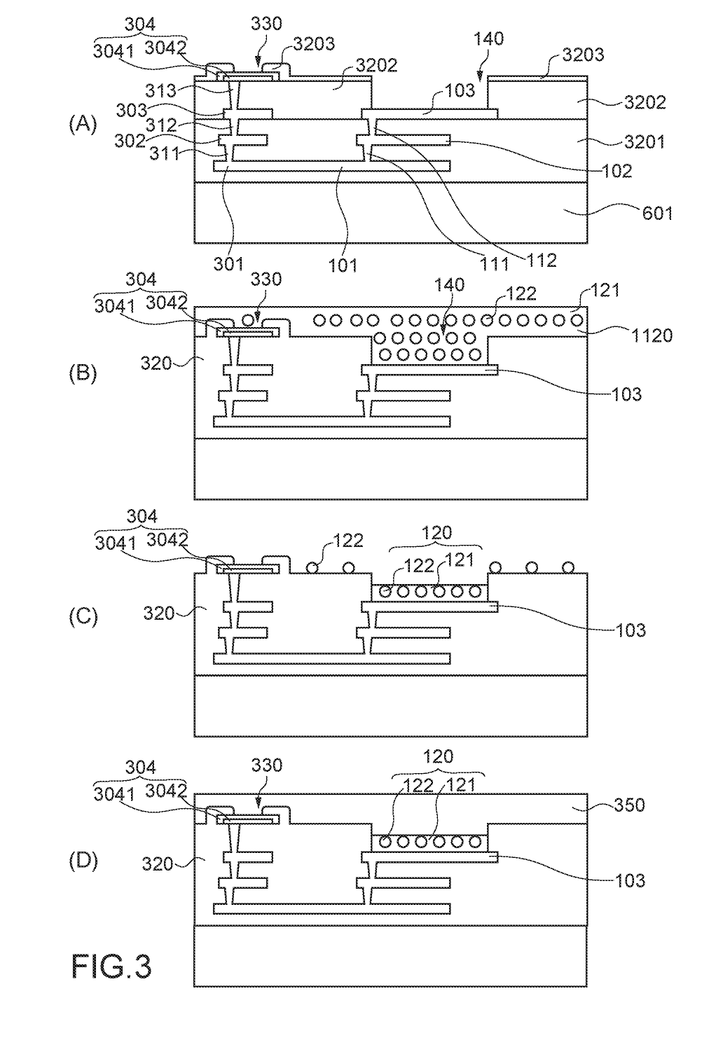

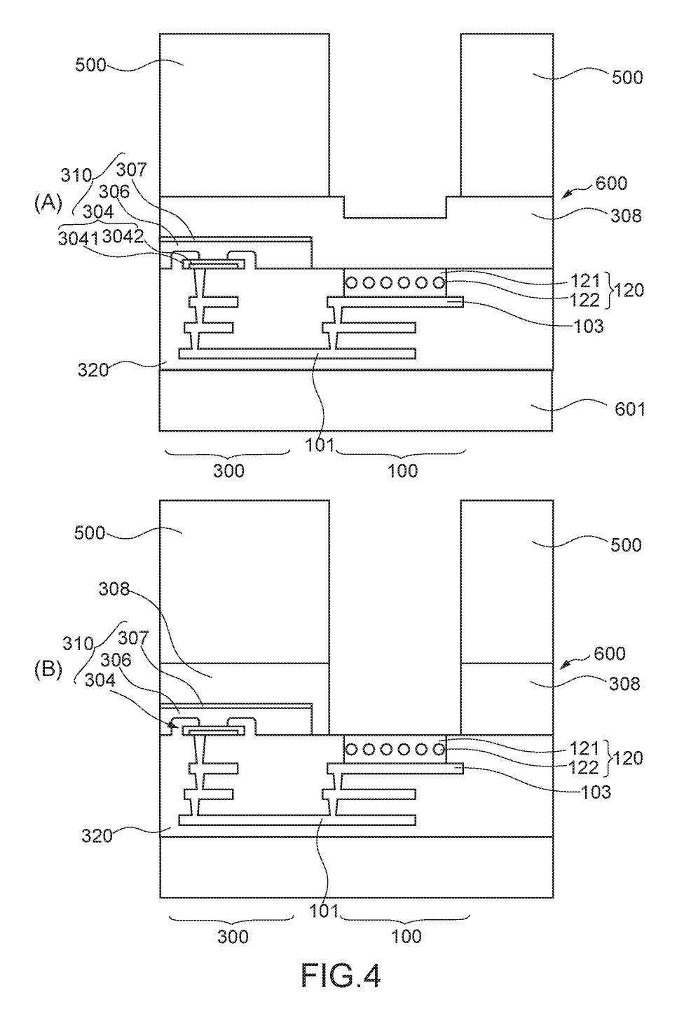

Subsequently, a method of manufacturing the organic EL display apparatus described above will be described with reference to FIG. 2, FIG. 3, and FIG. 4. FIG. 3 and FIG. 4 each are a diagram for explaining a part of a process of the method of manufacturing the organic EL display apparatus. The figures correspond to cross sections of the organic EL display apparatus shown in FIG. 2.

### First Embodiment

First, by a known manufacturing method, on the substrate 601, the metal layers 301 to 303 and a first interlayer insulation film 3201 are formed to form a drive transistor and a sampling transistor, the wiring 101, the metal layer 102, and the pad electrodes 103 are formed. The pad electrodes 103 is formed by using AlCu. The pad electrodes 103 are electrically connected to the wiring 101 through the connection hole 112, the metal layer 102, and the connection hole 111. Further, the metal layer 303 is electrically connected to the metal layer 301 through the connection hole 312, metal layer 302 and connection hole 311. The metal layer 301 and the wiring 101 are configured by the same layer and are electrically connected to each other.

Subsequently, on the metal layer 303, the pad electrodes 103, and the first interlayer insulation film 3201, a second interlayer insulation film 3202 is formed. On the second interlayer insulation film 3202, the connection hole 313 is formed. The AlCu layer 3042 as a part of the anode electrode 304 is formed so as to be electrically connected to the metal layer 303 through the connection hole 313. Subsequently, on the AlCu layer 3041, the ITO layer 3042 is formed, the anode electrode 304 formed by the laminated structure of the AlCu layer 3041 and ITO layer 3042 is formed on the second interlayer insulation film 3202.

Subsequently, on the anode electrode 304 and the second interlayer insulation film 3202, a third interlayer insulation film 3203 is formed.

Subsequently, the second interlayer insulation film 3202 and the third interlayer insulation film 3203 on the pad electrodes 103 in the pad area 100 are removed by dry etching, and on the second interlayer insulation film 3202 and the third interlayer insulation film 3203 on the pad electrodes 103, a second opening portion 140 is formed. As a result, the pad electrodes 103 made of AlCu is brought into an exposed state.

Subsequently, the third interlayer insulation film 3203 in an area corresponding to the pixels is removed by dry etching, and a first opening portion 330 is formed. As a result, as shown in FIG. 3(A), at least a part of the ITO layer 3042 of the anode electrode 304 is brought into an exposed state, and at least a part of the pad electrodes 103 is also brought into an exposed state. At this time, on a side wall of the first opening portion 330 and on the ITO layer 3042, there is process residue generated due to dry etching. It should be noted that in FIG. 2, the first interlayer insulation film 3201, the second interlayer insulation film 3202, the third interlayer insulation film 3203 are collectively shown as the interlayer insulation film 320. In the following description, the interlayer insulation films 3201 to 3203 are collectively referred to the interlayer insulation film 320.

Subsequently, as shown in FIG. 3(B), the ITO layer 3042 of the anode electrode 304 exposed, the pad electrodes 103, and the interlayer insulation film 320 are coated with an anisotropic conductive material obtained by mixing the metal particle 122 into the thermosetting resin 121, and thus an anisotropic conductive film 1120 is formed on an entire substrate.

Subsequently, to cause the anisotropic conductive film to remain only on the pad electrodes 103, a part of the anisotropic conductive film 1120 is removed by O₂ ashing (dry plasma process), and as shown in FIG. 3(C), the anisotropy conductive layer 120 is formed on the pad electrodes 103.

Here, to cause the anisotropic conductive film to remain only on the pad electrodes 103 selectively, EPD (End Point Detecting) control is used to perform ashing. When ashing proceeds, a film thickness of the anisotropic conductive film 1120 is decreased, and then the interlayer insulation film 320 is exposed. In the EPD, light having a specific wavelength, whose intensity is changed at a time when the interlayer insulation film 320 is exposed is measured and monitored at all times, thereby detecting the exposure of the interlayer insulation film 320.

Here, as shown in FIG. 3(A), the anode electrode 304 is formed on the second interlayer insulation film 3202 formed on the first interlayer insulation film 3201. On the other hand, the pad electrodes 103 is formed on the first interlayer insulation film 3201. As a result, the anode electrode 304 and the pad electrodes 103 are different in terms of a position to be formed in a thickness direction of the semiconductor substrate 600 by the thickness of the second interlayer insulation film 3202. Therefore, the second opening portion 140 formed in the pad area 100 is deeper than the first opening portion 330 formed in the display area 300 substantially by a thickness of the second interlayer insulation film 3202, which generates a large step difference.

At a time when the anisotropic conductive material is applied, and the anisotropic conductive film 1120 is smoothly formed on the entire substrate, as shown in FIG. 3(B), in the second opening portion 140 corresponding to the pad electrodes 103, the anisotropic conductive material enters, and thus the anisotropic conductive film 1120 is formed. As a result, the anisotropic conductive film 1120 formed on the pad electrodes 103 in the pad area 100 and the anisotropic conductive film 1120 formed on the anode electrode 304 in the display area 300 have different thicknesses. The anisotropic conductive film 1120 formed on the pad electrodes 103 is thicker. As described above, by performing ashing by using the thickness difference of opening portions between the second opening portion 140 corresponding to the pad electrodes 103 and the first opening portion 330 corresponding to the anode electrode 304, the exposure of the interlayer insulation film 320 is detected, and the anisotropy conductive layer 120 can be selectively formed on the pad electrodes 103. Further, by performing ashing, the thickness of the anisotropy conductive layer 120 can be set to a desired thickness. The thickness of the anisotropy conductive layer 120 is formed so as to be within the second opening portion 140, for example. For example, the thickness of the anisotropy conductive layer 120 can be set to be approximately half the depth of the second opening portion 140. As a result, at a time of forming the protection film 308 in a subsequent process, it is possible to form a film in such a manner that a surface of the protection film 308 is flat, and thus it is possible to prevent an occurrence of poor bonding between the semiconductor substrate 600 and the sealing substrate 500.

Subsequently, as shown in FIG. 3(C), to remove the metal particle 122 of the anisotropic conductive material that remains on part excluding the pad electrodes 103, scrubber cleaning by water washing is performed. Subsequently, as shown in FIG. 3(D), to remove process residue which exists on the side wall of the first opening portion 330 and on the ITO layer 3042 and which are generated due to dry etching at a time of the forming process of the first opening portion 330, the substrate 601 is immersed in an alkaline cleaning solution 350 to perform washing in such a manner that the anisotropy conductive layer 120, the ITO layer 3042 of the anode electrode 304, and the entire substrate including the interlayer insulation film 320 are exposed to the alkaline cleaning solution 350, which is a liquid containing an electrolyte. For a method of removing a polymer as a reactive product, as the alkaline cleaning solution 350, for example, TMAH (Tetramethylammonium hydroxide), an ammonium fluoride-based chemical solution, an organic amine system chemical solution can be used.

In this embodiment, at a time of cleaning by the alkaline cleaning solution 350, on the pad electrodes 103, the anisotropy conductive layer 120 is formed, so a battery effect by the alkaline cleaning solution 350 is not generated, and the ITO layer 3041 is not electrically corroded.

Here, in the case where the anisotropy conductive layer 120 is not formed on the pad electrodes 103, the pad electrodes 103 made of AlCu and the ITO layer 3042 of the anode electrode 304 are brought into an exposed state.

When the cleaning with the alkaline cleaning solution 350 is performed in a state in which the metals of different kinds, which have different oxidation-reduction potentials like AlCu and ITO are exposed, from the ITO layer 3042 of the anode electrode 304, OH⁻ is generated. OH⁻ causes a reaction expressed by the following expression (1) to be generated on the pad electrodes 103 made of AlCu, and thus electrons are generated. The anode electrode 304 and the ITO layer 3042 are electrically connected to each other. Therefore, an internal voltage difference of approximately 1 V between the ITO layer 3042 and the pad electrodes 103 causes a current path which has a low resistance to be generated. H₂O in the solution, electrons moved from AlCu (pad electrodes 103), and the ITO layer 3042 are reacted, and a reaction expressed by the following expression (2) is generated. Thus, In and OH⁻ are generated. Due to the battery effect as described above, the ITO layer 3042 is reduced, and as shown in FIG. 8, the ITO layer 3042 is subjected to electrical corrosion. A pixel having the anode electrode 304 becomes a dark spot at a time of being used in the organic EL display apparatus 1, with the result that a display characteristic is deteriorated. Further, In and the like is flown into the alkaline cleaning solution 350, and the cleaning solution may be polluted.

[Chemical 1]

Al+4OH⁻→H₂AlO₃⁻+H₂O+3e (1)

[Chemical 2]

In₂O₃+3H₂O+6e→2In+6OH⁻ (2)

[Chemical 3]

2H₂O+2e→2OH⁻+H₂ (3)

In contrast, in this embodiment, at a time of cleaning with the alkaline cleaning solution 350, the anisotropy conductive layer 120 is formed on the pad electrodes 103, and thus, it is possible to prevent the pad electrodes 103 and the alkaline cleaning solution 350 from being in contact. Further, the anisotropy conductive layer 120 has an insulation property because the anisotropy conductive layer 120 is in a state before thermal compression bonding is performed therefor, so a battery effect is not generated, and electrical corrosion of the ITO layer 3042 is not generated. As a result, it is possible to obtain the organic EL display apparatus 1 excellent in a display characteristic without a dark spot caused due to the electrical corrosion of the ITO layer 3042.

Subsequently, on the anode electrode 304, the organic EL layer 306 and the cathode electrode 307 are sequentially formed, and the organic EL element 310 is formed. Subsequently, on the entire substrate including the organic EL element 310, the protection film 308 is formed, and the semiconductor substrate 600 is formed.

Subsequently, the semiconductor substrate 600 and the sealing substrate 500 are bonded with a resin adhesive. After that, as shown in FIG. 4(A), the sealing substrate 500 in an area corresponding to the pad area 100 by a scrub. Subsequently, as shown in FIG. 4(B), by dry etching, the protection film 308 corresponding to the pad area 100 is removed, thereby causing the anisotropy conductive layer 120 to be exposed.

Then, as shown in FIG. 2, the ACF 400 is disposed on the anisotropy conductive layer 120, the flexible wiring substrate (not shown) is disposed on the ACF 400, and the thermal compression bonding is performed therefor. By performing pressurization while heating, the metal particles 122 of the anisotropy conductive layer 120 are superposed while being in contact. By being pressed, the metal particles 122 are bonded with each other, thereby forming a conduction path. In a similar way, in the ACF 400, the metal particles 402 in the ACF 400 are also superposed while being in contact. By being pressed, the metal particles 402 are bonded with each other, thereby forming a conduction path. Also, between the anisotropy conductive layer 120 and the ACF, the metal particles 122 and 402 are brought into contact to form a conduction path. As a result, the pad electrodes 103 and the flexible wiring substrate are electrically connected to each other through the anisotropy conductive layer 120 and ACF 400.

Subsequently, the flexible wiring substrate and the circuit substrate are electrically connected to each other, with the result that the organic EL display apparatus 1 is completed.

As described above, in the cleaning process with the use of the cleaning solution as a liquid containing the electrolyte, of two different kinds of the metal layers which are electrically connected and have different oxidation-reduction potentials, on one metal layer, the anisotropic conductive layer is formed. Therefore, the metal layer formed on the anisotropic conductive layer and the liquid containing the electrolyte are prevented from being in contact. Because the anisotropic conductive layer has the insulation property until being subjected to thermal compression bonding, the anisotropic conductive layer has the insulation property in the cleaning process. Thus, even if the layer is exposed to the liquid containing the electrolyte, the battery effect is not generated. It is possible to prevent an occurrence of corrosion of the metal layer.

Further, in the case where the metal layer on which the anisotropic conductive layer is formed is the pad electrode as the external connection terminal unit used for connection with outside, the anisotropic conductive layer can be used as a connection portion which electrically connects with outside, for example, the flexible wiring substrate. Further, until being subjected to thermal compression bonding, the anisotropic conductive layer has the insulation property. Therefore, during the manufacturing process, there is no need to remove the anisotropic conductive layer.

Further, in the cathode contact area 200, by the cleaning process described above, the ITO layer is brought into an exposed state. However, on the pad electrodes 103 made of AlCu, the anisotropy conductive layer 120 is formed, so the battery reaction is not caused, and electrical corrosion of the ITO layer in the cathode contact area 200 does not occur.

The method of manufacturing the anisotropic conductive layer is not limited to the above embodiment. For example, by a manufacturing method described in the following second embodiment or third embodiment, the anisotropic conductive layer may be manufactured. The method will be described below. Configurations similar to those in the above embodiment will be denoted by the similar symbols, a description of those may be omitted in some cases.

### Second Embodiment

In the first embodiment, as the anisotropic conductive layer, the material obtained by dispersing the metal particles in the thermosetting resin is used. A second embodiment is different from the first embodiment in that, as the anisotropic conductive layer, a material obtained by dispersing metal particles in resin capable of being subjected to pattern forming by photolithography is used.

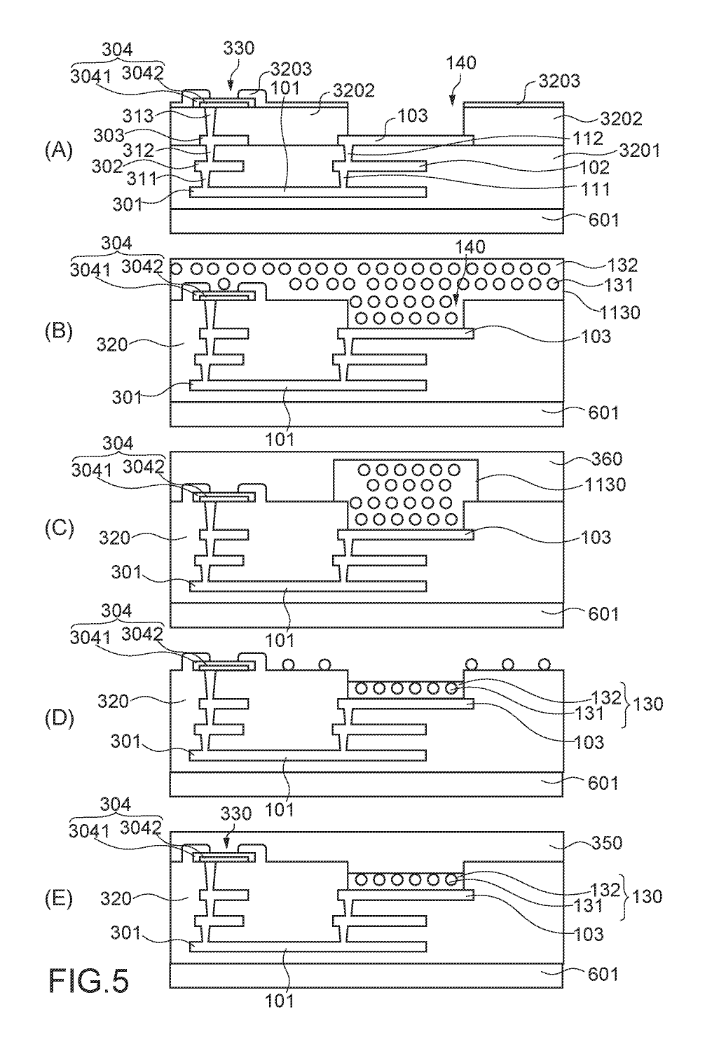

FIG. 5 is a process diagram showing a method of manufacturing an organic EL display apparatus according to the second embodiment. As in the first embodiment, FIG. 5 corresponds to a cross section of the organic EL display apparatus shown in FIG. 2.

First, as in the first embodiment, by a known manufacturing method, on the substrate 601, the metal layers 301 to 303 and the first interlayer insulation film 3201 are formed, and a drive transistor and a sampling transistor, the wiring 101, the metal layer 102, and the pad electrodes 103 are formed. Further, the second interlayer insulation film 3202, the anode electrode 304, and the third interlayer insulation film 3203 are formed.

Subsequently, the second interlayer insulation film 3202 and the third interlayer insulation film 3203 on the pad electrodes 103 in the pad area 100 are removed by dry etching, and the second opening portion 140 are formed on the second interlayer insulation film 3202 and the third interlayer insulation film 3203 on the pad electrodes 103. Subsequently, the third interlayer insulation film 3203 in an area corresponding to pixels is removed by dry etching, and the first opening portion 330 is formed. As a result, as shown in FIG. 5(A), at least a part of the ITO layer 3042 of the anode electrode 304 and the pad electrodes 103 is brought into an exposed state. At this time, on a side wall of the first opening portion 330 and on the ITO layer 3042, there is process residue generated by dry etching.

Subsequently, as shown in FIG. 5(B), on the ITO layer 3042 of the anode electrode 304, the pad electrodes 103, and interlayer insulation film 320 which are exposed, an anisotropic conductive material obtained by mixing metal particles 132 in a positive type light curing resin 131 is applied, thereby forming an anisotropic conductive film 1130. It should be noted that in this embodiment, the positive type light curing resin is used, but a negative type light curing resin may be used.

Subsequently, the anisotropic conductive film 1130 is exposed to light in such a manner that only on the pad electrodes 103, the anisotropic conductive film 1130 remains through a mask that covers the pad electrodes 103, and after that, development is performed. As shown in FIG. 5(C), in a development process by an alkaline developer 360 at a time of photolithography, on the pad electrodes 103, the anisotropic conductive film 1130 is formed. Therefore, like prevention of an occurrence of the electrical corrosion of the ITO layer 3042 due to a battery reaction by the liquid containing the electrolyte described in the first embodiment, an occurrence of electrical corrosion of the ITO layer 3041 due to a battery reaction by the alkaline developer 360 is prevented.

Subsequently, as shown in FIG. 5(D), to set a film thickness of the anisotropic conductive film 1130 that remains on the pad electrodes 103 to be a desired thickness, by O₂ ashing (dry plasma process), a part of the remaining anisotropic conductive film 1130 is removed by using EPD control, and on the pad electrodes 103, an anisotropic conductive layer 130 is formed.

Subsequently, as shown in FIG. 5(D), to remove metal particles 132 contained in the anisotropic conductive material that remains on the outside of the pad electrodes 103, scrubber cleaning by water washing is performed. Subsequently, as shown in FIG. 5 (E), to remove the process residue generated by dry etching on the side wall of the first opening portion 330 and on the ITO layer 3041 at the time of the forming process of the first opening portion 330, cleaning is performed with the alkaline cleaning solution 350 as a cleaning solution containing an electrolyte.

In this embodiment, as in the first embodiment, at the time of cleaning with the alkaline cleaning solution 350, the anisotropic conductive layer 130 is formed on the pad electrodes 103, so a battery effect due to the alkaline cleaning solution 350 does not occur, and electrical corrosion of the ITO layer 3041 is not caused.

Subsequently, on the anode electrode 304, the organic EL layer 306 and the cathode electrode 307 are sequentially formed, and the organic EL element 310 is formed. Subsequently, on the entire substrate including the organic EL element 310, the protection film 308 is formed, and the semiconductor substrate 600 is formed. The following manufacturing process is similar to that in the first embodiment. It should be noted that the anisotropic conductive layer 130 used in this embodiment is being pressurized while being heated like the anisotropy conductive layer 120 in the first embodiment, with the result that the metal particles 132 of the anisotropic conductive layer 130 are superposed while being in contact, and the metal particles 132 are bonded with each other, thereby forming a conduction path.

As described above, in the cleaning process of removal of the residue generated by dry etching and the alkaline cleaning process in the photolithography process, the anisotropic conductive layer 130 is formed on the pad electrodes 103, so a battery effect is not generated. Thus, it is possible to prevent an occurrence of electrical corrosion of the ITO layer.

### Third Embodiment

In the second embodiment, the anisotropic conductive film is exposed to light, development is performed, and then the part of the anisotropic conductive film that remains on the pad electrodes 103 is removed by O₂ ashing to adjust the thickness thereof. This embodiment is different from the second embodiment in that a thickness adjustment by O₂ ashing is not performed. In this embodiment, the O₂ ashing process is omitted, so there is no need to remove remaining metal particles that are generated by the O₂ ashing process. The scrubber cleaning can be omitted. Hereinafter, configurations similar to those in the second embodiment will be denoted by similar symbols, and a description thereof will be omitted in some cases.

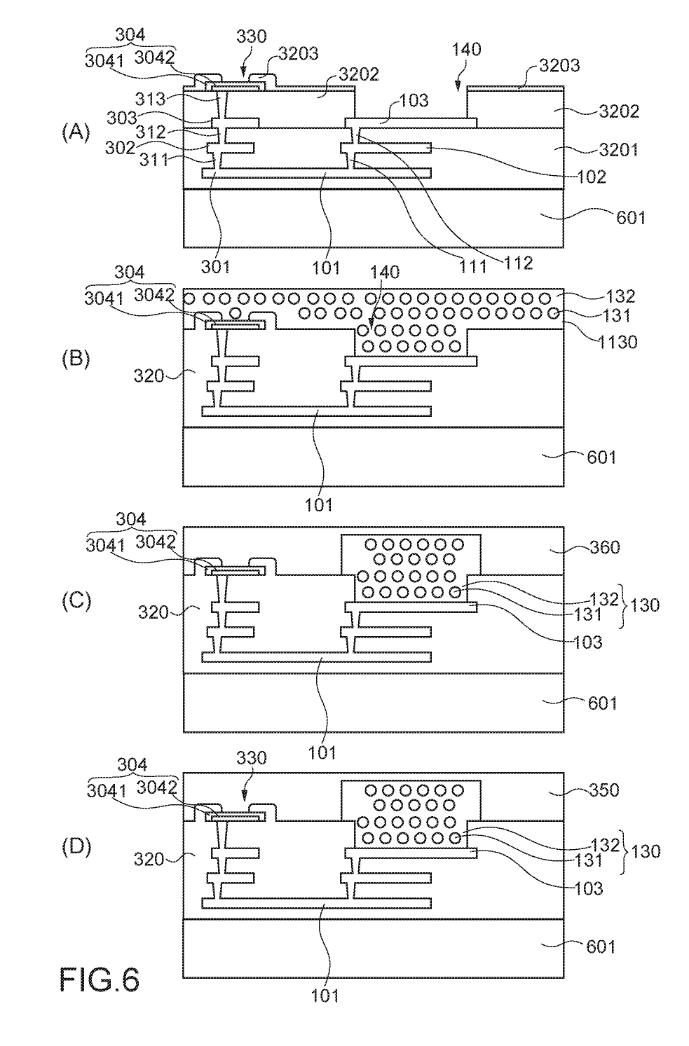

FIG. 6 is a process diagram showing a method of manufacturing an organic EL display apparatus according to a third embodiment. As in the first and second embodiments, FIG. 6 corresponds to a cross section of the organic EL display apparatus shown in FIG. 2.

First, as in the second embodiment, by a known manufacturing method, on the substrate 601, the metal layers 301 to 303 and the first interlayer insulation film 3201 are formed, and a drive transistor and a sampling transistor, the wiring 101, the metal layer 102, and the pad electrodes 103 are formed. Further, the second interlayer insulation film 3202, the anode electrode 304, and the third interlayer insulation film 3203 are formed.

Subsequently, the second interlayer insulation film 3202 and the third interlayer insulation film 3203 on the pad electrodes 103 in the pad area 100 are removed by dry etching, and the second opening portion 140 are formed on the second interlayer insulation film 3202 and the third interlayer insulation film 3203 on the pad electrodes 103. Subsequently, the third interlayer insulation film 3203 in an area corresponding to pixels is removed by dry etching, and the first opening portion 330 is formed. As a result, as shown in FIG. 6(A), at least part of each of the ITO layer 3042 of the anode electrode 304 and the pad electrodes 103 are brought into an exposed state. At this time, on a side wall of the first opening portion 330 and on the ITO layer 3042, there is process residue generated by dry etching.

Subsequently, as shown in FIG. 6(B), on the ITO layer 3042 of the anode electrode 304 exposed, the pad electrodes 103, and the interlayer insulation film 3203, an anisotropic conductive material obtained by mixing the metal particles 132 in the positive type light curing resin 131 is applied, thereby forming the anisotropic conductive film 1130.

Subsequently, the anisotropic conductive film 1130 is exposed to light through a mask that covers the pad electrodes 103 in such a manner that only on the pad electrodes 103, the anisotropic conductive film 1130 remains. After that, development is performed, and on the pad electrodes 103, the anisotropic conductive layer 130 is formed. As shown in FIG. 6(C), at the time of a development process by using the alkaline developer 360, the anisotropic conductive film 1130 is formed, and therefore an occurrence of electrical corrosion of the ITO layer due to a battery reaction by the alkaline developer 360 is prevented. As described above, the thickness of the anisotropy conductive layer 120 may be formed to be protruded from the second opening portion 140. In forming the protection film 308 in the subsequent process, it is sufficient that the protection film 308 can be formed to such an extent that a surface thereof is flat. It is possible to prevent an occurrence of poor bonding of the semiconductor substrate 600 and the sealing substrate 500.

Subsequently, as shown in FIG. 6(D), in order to remove process residue generated due to dry etching at the time of the forming process of the first opening portion 330 on the side wall of the first opening portion 330 and on the ITO layer 3042, cleaning is performed with the alkaline cleaning solution 350 as a cleaning solution containing an electrolyte.

In this embodiment, as in the second embodiment, at the time of cleaning with the alkaline cleaning solution 350, the anisotropic conductive layer 130 is formed on the pad electrodes 103, so a battery effect due to the alkaline cleaning solution 350 is not generated. Therefore, electrical corrosion of the ITO layer 3042 is not caused.

Subsequently, on the anode electrode 304, the organic EL layer 306 and the cathode electrode 307 are sequentially formed, thereby forming the organic EL element 310. Subsequently, on the entire substrate including the organic EL element 310, the protection film 308 is formed, and the semiconductor substrate 600 is formed. The subsequent manufacturing process is similar to that in the second embodiment.

As described above, in the cleaning process of removal of the residue generated by dry etching and in the alkaline cleaning process in the photolithography process, the anisotropic conductive layer 130 is formed on the pad electrodes 103. Therefore, a battery effect is not generated, and it is possible to prevent an occurrence of electrical corrosion of the ITO layer.

### Electronic Apparatus

The organic EL display apparatus is incorporated in various electronic apparatuses as in application examples 1 and 2 to be described later, for example. It should be noted that the application examples are not limited to those, and the apparatus can be applied to a video camera, a mobile phone, and the like, for example.

### Application Example 1

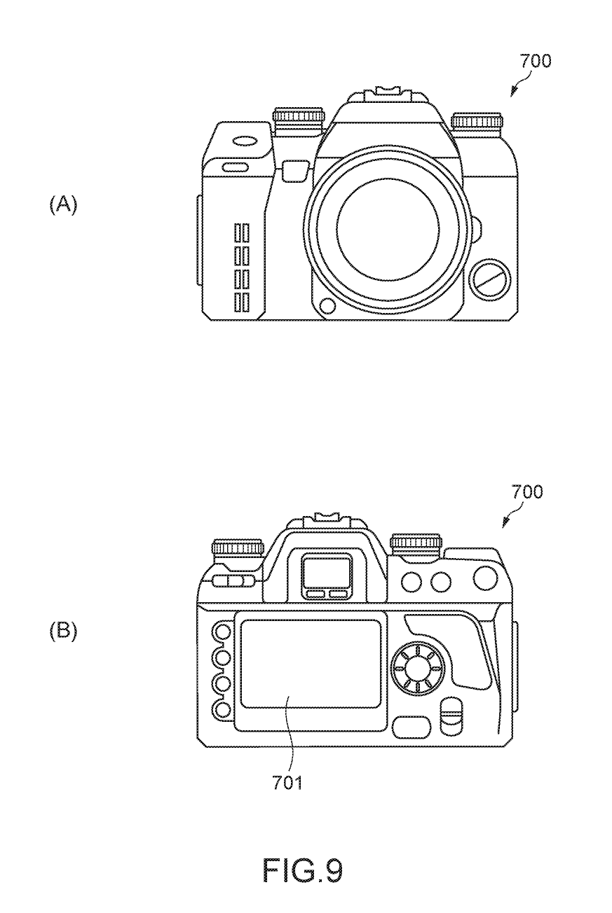

FIG. 9 is a diagram showing an external view of a digital camera. FIG. 9(A) is a front view of a digital camera 700, and FIG. 9(B) is a back view of the digital camera 700. The digital camera 700 has a viewfinder unit 701. For the viewfinder unit 701, the organic EL display apparatus is used.

### Application Example 2

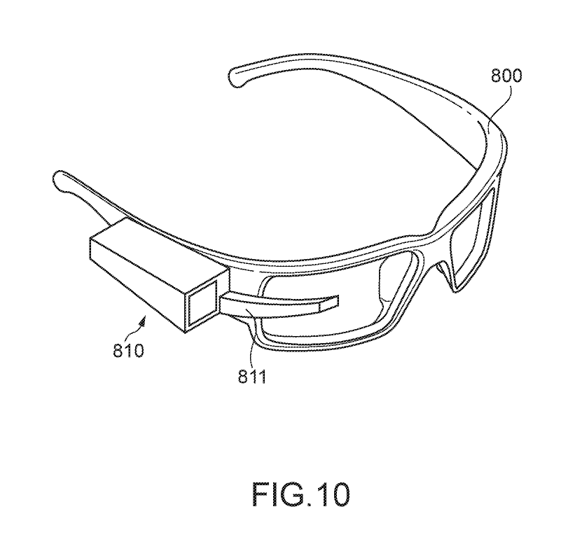

FIG. 10 is an external view in which an eyewear-mounted type one-eye display module 810 is mounted on an eyewear 800 such as glasses, goggles, and sunglasses.

The eyewear-mounted type one-eye display module 810 includes a control substrate and an organic EL display apparatus 811. For the organic EL display apparatus 811, the organic EL display apparatus is used.

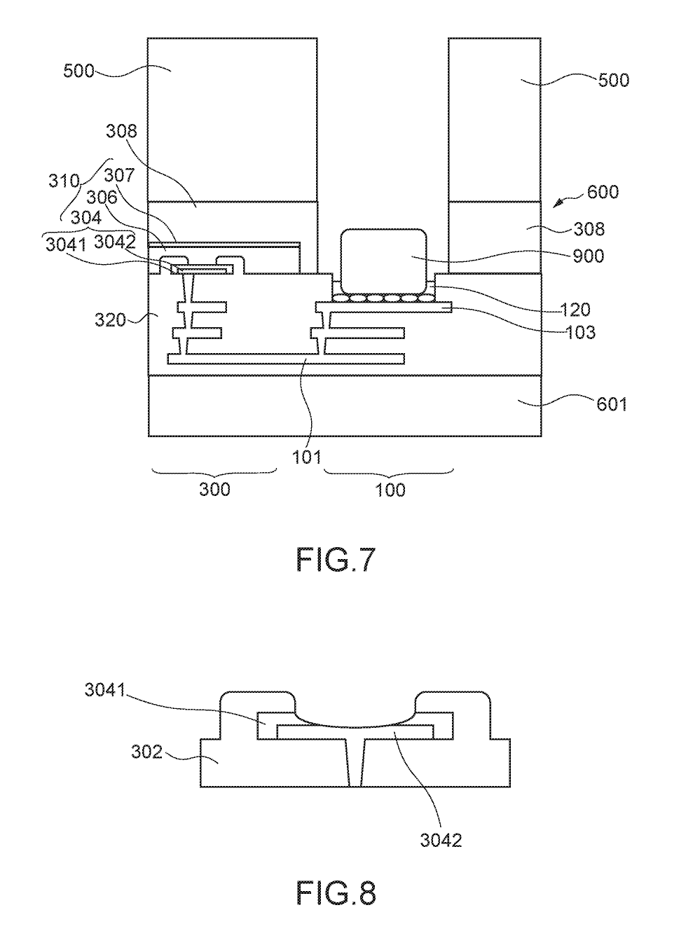

As described above, the present technology is not limited to those embodiments and the like, and can be variously modified. For example, in the above embodiments, through the anisotropic conductive layer and the ACF, the pad electrode and the flexible wiring substrate are electrically connected to each other. However, unlike the case as shown in FIG. 7, such a configuration that the pad electrodes 103 and the flexible wiring substrate 900 are electrically connected to each other through the anisotropy conductive layer 120 without using the ACF may be used.

Further, in the above embodiments, as the metal materials of different kind having different oxidation-reduction potentials, the ITO (the first electrode or the third electrode, the anode electrode in the embodiments or the metal layer in the cathode contact area) and AlCu (the second electrode, the pad electrode) are cited as the example, but the materials are not limited thereto. For example, instead of the ITO, an IZO (Indium Zinc Oxide), a ZTO (Zinc Tin Oxide), SnO₂, PbO₂, and CdO can be used. Further, instead of AlCu, an Al—Ni-based alloy, Al, Ag, an Ag alloy, Cu, a Cu alloy, Au, and an Au alloy can also be used.

It should be noted that the present technology can take the following configurations.

(1) A method of manufacturing a display apparatus, including:

forming a first electrode having a first conductive material on a substrate;

forming, on the substrate, a second electrode having a second conductive material different from the first conductive material, the second electrode being electrically connected to the first electrode;

forming an interlayer insulation film to cover the first electrode and the second electrode;

forming a first opening portion on the interlayer insulation film and causing at least a part of the first electrode to be exposed;

forming a second opening portion on the interlayer insulation film and causing at least a part of the second electrode to be exposed;

forming an anisotropic conductive layer on the exposed second electrode; and

exposing, after the anisotropic conductive layer is formed, the first opening portion, the second opening portion, and the interlayer insulation film to a liquid containing an electrolyte.

(2) The method of manufacturing a display apparatus according to (1) described above, in which

the first electrode is formed in a display area of the substrate, and the second electrode is formed in a first area outside of the display area of the substrate.

(3) The method of manufacturing a display apparatus according to (1) or (2) described above, in which

the interlayer insulation film includes a first interlayer insulation film, a second interlayer insulation film, and a third interlayer insulation film,

the second electrode is formed on the first interlayer insulation film,

after the second electrode is formed, on the second electrode and the first interlayer insulation film, the second interlayer insulation film is formed,

after the second interlayer insulation film is formed, on the second interlayer insulation film, the first electrode is formed, and

after the first electrode is formed, on the first electrode and the second interlayer insulation film, the third interlayer insulation film is formed.

(4) The method of manufacturing a display apparatus according to (3) described above, in which

the anisotropic conductive layer is formed by
forming an anisotropic conductive film on an exposed portion of the first electrode, an exposed portion of the second electrode, and the interlayer insulation film, and
performing ashing for the anisotropic conductive film by using EPD control in such a manner that the anisotropic conductive film remains only on the exposed second electrode.

(5) The method of manufacturing a display apparatus according to any one of (1) to (3) described above, in which

the anisotropic conductive layer is formed by
forming an anisotropic conductive film including a light curing resin on an exposed portion of the first electrode, an exposed portion of the second electrode, and the interlayer insulation film, and
causing the anisotropic conductive film to be exposed to light and performing development in such a manner that the anisotropic conductive film remains only on the exposed second electrode.

(6) The method of manufacturing a display apparatus according to any one of (1) to (5) described above, in which

the second electrode and a wiring substrate are disposed to face each other through the anisotropic conductive layer, and the second electrode and the wiring substrate are electrically connected by thermal compression bonding.

(7) The method of manufacturing a display apparatus according to any one of (1) to (6) described above, in which

the first conductive material and the second conductive material have different oxidation-reduction potentials.

(8) The method of manufacturing a display apparatus according to any one of (1) to (7) described above, in which

the first conductive material is a transparent conductive material, and the second conductive material is a material containing aluminum.

(9) The method of manufacturing a display apparatus according to any one of (1) to (8) described above, in which

the first conductive material is an indium tin oxide, and the second conductive material is an aluminum copper alloy.

(10) The method of manufacturing a display apparatus according to any one of (1) to (9) described above, in which

the first electrode has a laminated structure of a first conductive layer made of the second conductive material and a second conductive layer that is provided on the first conductive layer and made of the first conductive material.

(11) The method of manufacturing a display apparatus according to (1) described above, in which

the first electrode is formed in a second area outside of a display area of the substrate, and the second electrode is formed in a first area outside of the display area of the substrate.

(12) A display apparatus, including:

a substrate including a display area;

an organic electroluminescence element including a first electrode that is provided in the display area and has a first conductive material, an organic electroluminescence layer provided on the first electrode, and a third electrode provided on the organic electroluminescence layer;

a second electrode that is provided outside of the display area of the substrate, is electrically connected to the first electrode, and has a second conductive material having the first conductive material; and

an anisotropic conductive layer provided on the second electrode.

(13) The display apparatus according to (12) described above, in which

the first conductive material and the second conductive material have different oxidation-reduction potentials.

(14) The display apparatus according to (12) or

(13) described above, further including:

a wiring substrate electrically connected to the second electrode through the anisotropic conductive layer.

(15) An electronic apparatus, including:

a display apparatus including
a substrate including a display area,
an organic electroluminescence element including a first electrode that is provided in the display area and has a first conductive material, an organic electroluminescence layer provided on the first electrode, and a third electrode provided on the organic electroluminescence layer,
a second electrode that is provided outside of the display area of the substrate, is electrically connected to the first electrode, and has a second conductive material having the first conductive material, and
an anisotropic conductive layer provided on the second electrode.

### REFERENCE SIGNS LIST

1 . . . organic EL display apparatus
100 . . . pad area (first area)
103 . . . pad electrode (second electrode)
120, 130 . . . anisotropic conductive layer
140 . . . second opening portion
200 . . . cathode contact area (second area)
300 . . . display area
304 . . . anode electrode (first electrode)
306 . . . organic EL layer
307 . . . cathode electrode (third electrode)
310 . . . organic electroluminescence element
320 . . . interlayer insulation film
330 . . . first opening portion
350 . . . alkaline cleaning solution (liquid containing an electrolyte)
360 . . . alkaline developer (liquid containing an electrolyte)
700 . . . digital camera (electronic apparatus)
701 . . . viewfinder unit
810 . . . eyewear-mounted type one-eye display module (electronic apparatus)
811 . . . organic EL display apparatus
900 . . . flexible wiring substrate
3041 . . . ITO layer (second conductive layer)
3042 . . . AlCu layer (first conductive layer)
3201 . . . first interlayer insulation film
3202 . . . second interlayer insulation film
3203 . . . third interlayer insulation film

1. A method of manufacturing a display apparatus, comprising:
forming a first electrode having a first conductive material on a substrate;
forming, on the substrate, a second electrode having a second conductive material different from the first conductive material, the second electrode being electrically connected to the first electrode;
forming an interlayer insulation film to cover the first electrode and the second electrode;
forming a first opening portion on the interlayer insulation film and causing at least a part of the first electrode to be exposed;
forming a second opening portion on the interlayer insulation film and causing at least a part of the second electrode to be exposed;
forming an anisotropic conductive layer on the exposed second electrode; and
exposing, after the anisotropic conductive layer is formed, the first opening portion, the second opening portion, and the interlayer insulation film to a liquid containing an electrolyte.

2. The method of manufacturing a display apparatus according to claim 1, wherein
the first electrode is formed in a display area of the substrate, and the second electrode is formed in a first area outside of the display area of the substrate.

3. The method of manufacturing a display apparatus according to claim 2, wherein
the interlayer insulation film includes a first interlayer insulation film, a second interlayer insulation film, and a third interlayer insulation film,
the second electrode is formed on the first interlayer insulation film,
after the second electrode is formed, on the second electrode and the first interlayer insulation film, the second interlayer insulation film is formed,
after the second interlayer insulation film is formed, on the second interlayer insulation film, the first electrode is formed, and
after the first electrode is formed, on the first electrode and the second interlayer insulation film, the third interlayer insulation film is formed.

4. The method of manufacturing a display apparatus according to claim 3, wherein
the anisotropic conductive layer is formed by
forming an anisotropic conductive film on an exposed portion of the first electrode, an exposed portion of the second electrode, and the interlayer insulation film, and
performing ashing for the anisotropic conductive film by using EPD control in such a manner that the anisotropic conductive film remains only on the exposed second electrode.

5. The method of manufacturing a display apparatus according to claim 3, wherein
the anisotropic conductive layer is formed by
forming an anisotropic conductive film including a light curing resin on an exposed portion of the first electrode, an exposed portion of the second electrode, and the interlayer insulation film, and
causing the anisotropic conductive film to be exposed to light and performing development in such a manner that the anisotropic conductive film remains only on the exposed second electrode.

6. The method of manufacturing a display apparatus according to claim 4, wherein
the second electrode and a wiring substrate are disposed to face each other through the anisotropic conductive layer, and the second electrode and the wiring substrate are electrically connected by thermal compression bonding.

7. The method of manufacturing a display apparatus according to claim 6, wherein
the first conductive material and the second conductive material have different oxidation-reduction potentials.

8. The method of manufacturing a display apparatus according to claim 7, wherein
the first conductive material is a transparent conductive material, and the second conductive material is a material containing aluminum.

9. The method of manufacturing a display apparatus according to claim 8, wherein
the first conductive material is an indium tin oxide, and the second conductive material is an aluminum copper alloy.

10. The method of manufacturing a display apparatus according to claim 9, wherein
the first electrode has a laminated structure of a first conductive layer made of the second conductive material and a second conductive layer that is provided on the first conductive layer and made of the first conductive material.

11. The method of manufacturing a display apparatus according to claim 1, wherein
the first electrode is formed in a second area outside of a display area of the substrate, and the second electrode is formed in a first area outside of the display area of the substrate.

12. A display apparatus, comprising:
a substrate including a display area;
an organic electroluminescence element including a first electrode that is provided in the display area and has a first conductive material, an organic electroluminescence layer provided on the first electrode, and a third electrode provided on the organic electroluminescence layer;
a second electrode that is provided outside of the display area of the substrate, is electrically connected to the first electrode, and has a second conductive material having the first conductive material; and
an anisotropic conductive layer provided on the second electrode.

13. The display apparatus according to claim 12, wherein
the first conductive material and the second conductive material have different oxidation-reduction potentials.

14. The display apparatus according to claim 13, further comprising:
a wiring substrate electrically connected to the second electrode through the anisotropic conductive layer.

15. An electronic apparatus, comprising:
a display apparatus including
a substrate including a display area,
an organic electroluminescence element including a first electrode that is provided in the display area and has a first conductive material, an organic electroluminescence layer provided on the first electrode, and a third electrode provided on the organic electroluminescence layer,
a second electrode that is provided outside of the display area of the substrate, is electrically connected to the first electrode, and has a second conductive material having the first conductive material, and
an anisotropic conductive layer provided on the second electrode.
